(19) United States
(12) Patent Application Publication
(10) Pub. No.: US 2026/0107687 A1
(43) Pub. Date: Apr. 16, 2026

(54) THERMOELECTRIC CONVERSION ELEMENT AND SENSOR

(71) Applicant: NITTO DENKO CORPORATION, Ibaraki-shi, Osaka (JP)

(72) Inventors: Hirokazu TANAKA, Ibaraki-shi, Osaka (JP); Yosuke NAKANISHI, Ibaraki-shi, Osaka (JP); Manami KUROSE, Ibaraki-shi, Osaka (JP); Takahiro NAKAI, Ibaraki-shi, Osaka (JP)

(21) Appl. No.: 19/116,186

(22) PCT Filed: Sep. 29, 2023
(86) PCT No.: PCT/JP2023/035777

§ 371 Date: Mar. 27, 2025

(30) Foreign Application Priority Data
Sep. 29, 2022 (JP) 2022-156711

(51) Int. Cl. H10N 10/17; H10N 10/851

(52) U.S. Cl. CPC H10N 10/17; H10N 10/851

(57) ABSTRACT

A thermoelectric conversion element includes a thermoelectric conversion body and a connection portion. The thermoelectric conversion body includes a conductive magnetic body having a ferromagnetic body or an antiferromagnetic body capable of exhibiting an anomalous Nernst effect, and extends linearly. The connection portion includes a conductive body and is electrically connected to the thermoelectric conversion body. The connection portion has a layered structure of a plurality of conductive layers. The layered structure includes a first conductive layer and a second conductive layer. The first conductive layer has a Seebeck coefficient lower than a Seebeck coefficient of the conductive magnetic body included in the thermoelectric conversion body. The second conductive layer has a Seebeck coefficient higher than the Seebeck coefficient.

### TECHNICAL FIELD

The present invention relates to a thermoelectric conversion element and a sensor.

### BACKGROUND ART

Techniques relating to magneto-thermoelectric conversion have been known.

For example, Patent Literature 1 describes a thermoelectric generation device utilizing an anomalous Nernst effect. The anomalous Nernst effect is a phenomenon that a voltage is generated in a direction orthogonal to both a magnetization direction and a temperature gradient when a temperature difference is caused by a heat flow through a magnetic body.

This thermoelectric generation device includes a substrate, a power generation body, and a connection body. The power generation body is formed of a plurality of thin wires disposed in parallel to each other along a surface of the substrate. Each thin wire is formed by shaping an FePt thin film formed on the substrate into a thin strip, and the thin wires are magnetized in the width direction. The power generation body is configured to generate electricity using a temperature difference in the direction perpendicular to the direction of magnetization due to the anomalous Nernst effect. The connection body is composed of a plurality of thin wires disposed along the surface of the substrate, parallel to and between the respective thin wires of the power generation body. Each thin wire of the connection body electrically connects one end part of each thin wire of the power generation body to an end part of another thin wire adjacent on one side to the first-described thin wire. In this manner, the connection body electrically connects the respective thin wires of the power generation body in series. The connection body is, for example, formed of Cr as a non-magnetic body.

### CITATION LIST

### Patent Literature

JP 2014-072256 A

### SUMMARY OF INVENTION

### Technical Problem

In monitoring of physical condition in the Internet of Things (IOT) society or in thermal management in the technical field such as batteries for electric vehicle (EV) or chips for high-speed data processing, the needs for heat monitoring have been increased. For complying with such needs, use of a thermoelectric conversion element for thermal sensing may be taken into consideration.

It is understood that a thermoelectric conversion element utilizing magneto-thermoelectric conversion, such as the thermoelectric conversion device described in Patent Literature 1, can be manufactured more easily than a thermoelectric generation device utilizing the Seebeck effect. Taking these advantages into consideration, it is conceivable to use a thermoelectric conversion element utilizing magneto-thermoelectric conversion for heat sensing.

In the thermoelectric conversion device described in Patent Literature 1, the power generation body is configured to generate electricity using a temperature difference in a direction perpendicular to the direction of magnetization. On the other hand, in a thermoelectric conversion element utilizing magneto-thermoelectric conversion, it is assumed that an electromotive force is generated by a mechanism different from that of the magneto-thermoelectric conversion. For example, in the thermoelectric conversion device described in Patent Literature 1, when a temperature gradient occurs in the length direction of thin wires of a power generation body made of FePt thin film and thin wires of a connection body made of a non-magnetic body of Cr, a thermal electromotive force resulting from the Seebeck effect can be generated in the length direction due to the difference between the Seebeck coefficient of the FePt and the Seebeck coefficient of the Cr. Generation of the thermal electromotive force is probably not advantageous from the viewpoint of thermal sensing accuracy, because the electromotive force resulting from the Seebeck effect is superimposed on the electromotive force caused by the magneto-thermoelectric conversion. In addition to that, in the thermoelectric conversion device described in Patent Literature 1, a connection body formed of a plurality of thin wires is electrically connected in series to the power generation body made of a plurality of thin wires in order to increase the thermal electromotive force resulting from the magneto-thermoelectric effect. In such a configuration, the electromotive force resulting from the Seebeck effect tends to increase, which may have a significant impact on the accuracy of thermal sensing.

The magneto-thermoelectric coefficient Sₙₑ is expressed by a relational expression Sₙₑ=βₓₓα_{xy}−Sₛₑ·σ_{xy}/σₓₓ, using an electrical specific resistance ρₓₓ, a transverse magneto-thermoelectric coefficient α_{xy}, a Seebeck coefficient Sₛₑ, and hole conductivities σ_{xy} and σₓₓ. Therefore, from the viewpoint of improving the performance of magneto-thermoelectric conversion, it is understood that a material with a large absolute value of Seebeck coefficient Sₛₑ is advantageous. Use of a material with a large Seebeck coefficient Sₛₑ may increase the magneto-thermoelectric coefficient Sₙₑ, thereby improving the thermoelectric conversion performance. Meanwhile, a material with a large Seebeck coefficient Sₛₑ is likely to generate electromotive force due to a temperature difference in the in-plane direction, which tends to affect the accuracy of thermal sensing. Attempts have been made to apply Heusler alloys or the like represented by Co₂MnGa, which have a large Seebeck Sₛₑ coefficient, to magneto-thermoelectric conversion elements, but no consideration has been given to dealing with such issues.

In view of such circumstances, the present invention provides a thermoelectric conversion element that is advantageous from the viewpoint of improving the accuracy of heat sensing while utilizing magneto-thermoelectric conversion.

### Solution to Problem

The present invention provides a thermoelectric conversion element including:
a thermoelectric conversion body including a conductive magnetic body containing a ferromagnetic body or an antiferromagnetic body capable of exhibiting an anomalous Nernst effect, and the thermoelectric conversion body extending linearly; and
a connection portion including a conductive body and electrically connected to the thermoelectric conversion body, wherein
the connection portion has a layered structure composed of a plurality of conductive layers, and
the layered structure includes a first conductive layer having a Seebeck coefficient lower than a Seebeck coefficient of the conductive magnetic body, and a second conductive layer having a Seebeck coefficient higher than the Seebeck coefficient of the conductive magnetic body.

The present invention provides a thermoelectric conversion element including:
a thermoelectric conversion body including a conductive magnetic body containing a ferromagnetic body or an antiferromagnetic body capable of exhibiting an anomalous Nernst effect, and the thermoelectric conversion body extending linearly; and
a connection portion including a conductive body and electrically connected to the thermoelectric conversion body, wherein
the connection portion has a layered structure composed of a plurality of conductive layers, and
an absolute value of a difference between a Seebeck coefficient of the connection portion and a Seebeck coefficient of the conductive magnetic body is 5 μV/K or less.

### Advantageous Effects of Invention

The thermoelectric conversion element described above is advantageous from the viewpoint of improving the accuracy of heat sensing while utilizing magneto-thermoelectric conversion.

### BRIEF DESCRIPTION OF DRAWINGS

FIG. 1 is a perspective view showing an example of an embodiment of a thermoelectric conversion element.

FIG. 2 is a cross-sectional view of a thermoelectric conversion element with a plane II shown in FIG. 1 as a cutting plane.

FIG. 3 is a cross-sectional view showing another example of a thermoelectric conversion element.

FIG. 4 shows a cross-sectional view of still another example of a thermoelectric conversion element.

FIG. 5 shows a cross-sectional view of still another example of a thermoelectric conversion element.

### DESCRIPTION OF EMBODIMENTS

Embodiments of the present invention are explained with reference to the attached drawings. The present invention is not limited to the following embodiments. In the attached drawings, the X-axis, Y-axis, and Z-axis are mutually orthogonal.

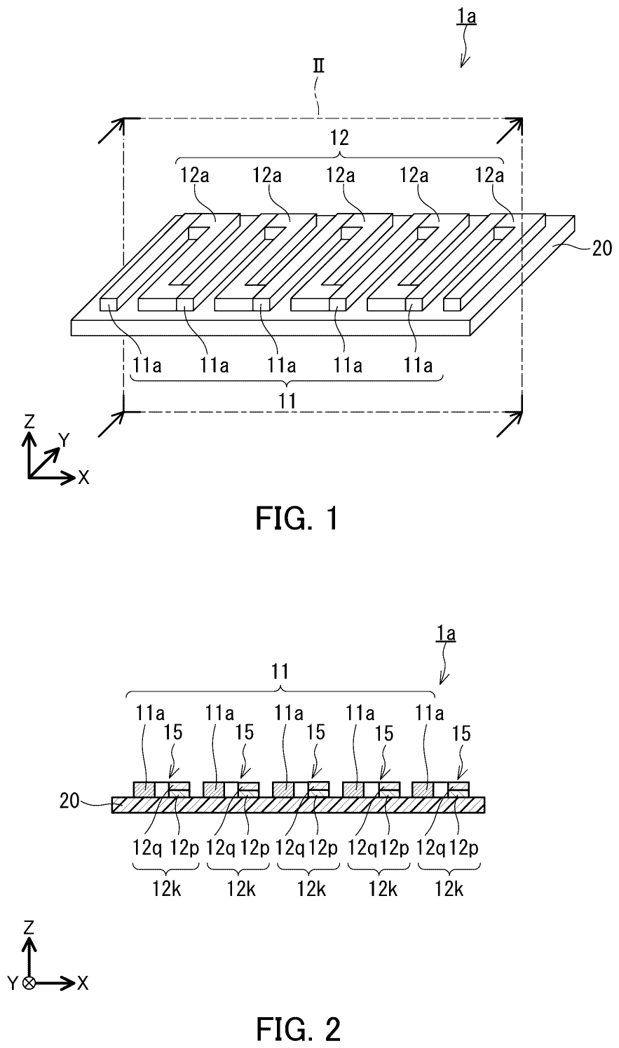

As shown in FIG. 1, a thermoelectric conversion element 1a includes a thermoelectric conversion body 11 and a connection portion 12. The thermoelectric conversion body 11 includes a conductive magnetic body containing a ferromagnetic body or an antiferromagnetic body exhibiting an anomalous Nernst effect, and the thermoelectric conversion body 11 extends linearly. The connection portion 12 includes a conductive body and is electrically connected to the thermoelectric conversion body 11. As shown in FIG. 2, the connection portion 12 has a layered structure 12k composed of a plurality of conductive layers. The layered structure 12k includes, for example, a first conductive layer 12p and a second conductive layer 12q. The first conductive layer 12p has a Seebeck coefficient lower than a Seebeck coefficient Sₘ of the conductive magnetic body included in the thermoelectric conversion body 11. The second conductive layer 12q has a Seebeck coefficient higher than the Seebeck coefficient Sₘ. The Seebeck coefficient of each conductive layer of the layered structure 12k and the Seebeck coefficient Sₘ are, for example, values at a temperature in a range of 25 to 40° C., and the coefficients can be measured in accordance with the method described in Examples. The thermoelectric conversion body 11 and the connection portion 12 are, for example, arranged along a plane parallel to an XY plane.

In the thermoelectric conversion element 1a, when a temperature gradient occurs in the length direction (Y-axis direction) of the thermoelectric conversion body 11, a thermal electromotive force resulting from the Seebeck effect may be generated in the length direction due to the difference between a Seebeck coefficient S_{L} of the connection portion 12 and the Seebeck coefficient Sₘ. Since the connection portion 12 has the layered structure 12k including a first conductive layer 12p and a second conductive layer 12q, the Seebeck coefficient S_{L} of the connection portion 12 can take a value between the Seebeck coefficient of the first conductive layer 12p and the Seebeck coefficient of the second conductive layer 12q. As a result, the difference between the Seebeck coefficient S_{L} of the connection portion 12 and the Seebeck coefficient Sₘ tends to be small, and thus, even if a temperature gradient occurs in the length direction of the thermoelectric conversion body 11, the thermal electromotive force resulting from the Seebeck effect in the length direction tends to be small. Therefore, in a sensing using the thermoelectric conversion element 1a, the electromotive force resulting from the Seebeck effect, which is superimposed on the electromotive force caused by the magneto-thermoelectric conversion, tends to be smaller. As a result, the thermoelectric conversion element 1a is advantageous from the viewpoint of realizing a highly accurate heat sensing by using magneto-thermoelectric conversion.

In the case where the connection portion electrically connected to the thermoelectric conversion body including the conductive magnetic body is composed of a single conductive layer, it is considered that the Seebeck coefficient of the conductive body composing the conductive layer can be made close to the Seebeck coefficient of the conductive magnetic body. For example, it is considered that the Seebeck coefficient of the conductive layer is adjusted by varying the composition of the components contained in the single conductive layer. However, in this case, there is a possibility that the Seebeck coefficient of the conductive layer will considerably fluctuate due to a fluctuation in the composition of the components contained in the single conductive layer, and thus, favorable robustness may not be exhibited. In addition, even if it is possible to adjust the Seebeck coefficient of the conductive layer to a value close to the Seebeck coefficient of the conductive magnetic body, the composition of the conductive layer will be determined to a specific one, which may impose restrictions on realization of other properties such as durability of the conductive layer.

On the other hand, researches by the present inventors have newly clarified that the Seebeck coefficient of the layered structure can be roughly predicted based on the Seebeck coefficient, specific resistance, and thickness of each layer of the layered structure. For example, in the thermoelectric conversion element 1a, the Seebeck coefficient S_{L} of the connection portion 12 can take a value between the Seebeck coefficient of the first conductive layer 12p and the Seebeck coefficient of the second conductive layer 12q. In this case, for example, by adjusting the thickness of the first conductive layer 12p and the thickness of the second conductive layer 12q, the difference between the Seebeck coefficient S_{L} of the connection portion 12 and the Seebeck coefficient Sₘ can be reduced. As described above, in this thermoelectric conversion element 1a, since few restrictions are imposed on the electric conductive body in adjustment of the Seebeck coefficient S_{L} of the connection portion 12, the Seebeck coefficient S_{L} can be easily adjusted and favorable robustness is exhibited. In addition, it is possible to select a material that is advantageous from the viewpoint of other properties such as durability for the conductive body included in the connection portion 12, thereby enhancing the added value of the thermoelectric conversion element 1a.

In the thermoelectric conversion element 1a, an absolute value |S_{L}-Sₘ| of a difference between the Seebeck coefficient S_{L} of the connection portion 12 and the Seebeck coefficient Sₘ is not limited to a specific value. For example, the absolute value |S_{L}-Sₘ| is 5 μV/K or less. In this case, the thermoelectric conversion element 1a is advantageous from the viewpoint of realizing highly accurate thermal sensing by use of magneto-thermoelectric conversion. The Seebeck coefficient S_{L} of the connection portion 12 is, for example, a value at a temperature in the range of 25 to 40° C., and can be measured according to the method described in Examples.

In the thermoelectric conversion element 1a, |S_{L}-Sₘ| may be 4.8 μV/K or less, may be 4.5 μV/K or less, may be 4.0 μV/K or less, may be 3.5 μV/K or less, or may be 3.0 μV/K or less. The |S_{L}-Sₘ| may be 2.5 V/K or less, may be 2.0 μV/K, may be 1.0 μV/K or less, may be 0.5 μV/K or less, or may be 0.3 μV/K or less.

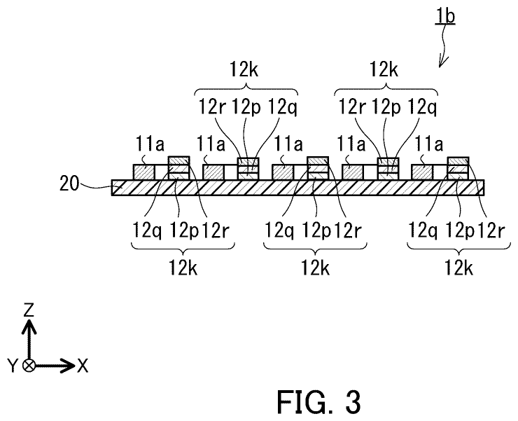

In the thermoelectric conversion element 1a, the number n of the conductive layers included in the layered structure 12k is not limited to a specific value. As shown in FIG. 2, n may be 2 in the layered structure 12k, and the layered structure 12k may be composed of only two conductive layers, namely, the first conductive layer 12p and the second conductive layer 12q. FIG. 3 is a cross-sectional view showing another example of a thermoelectric conversion element. A thermoelectric conversion element 1b shown in FIG. 3 is composed similarly to the thermoelectric conversion element 1a, except for the parts that are specifically explained. As shown in FIG. 3, in the layered structure 12k, n may be 3, and the layered structure 12k may further include a third conductive layer 12r. The layered structure 12k may include four or more conductive layers. The number n of the conductive layers included in the layered structure 12k is, for example, 10 or less, and may be 5 or less.

The thermoelectric conversion element 1a, for example, satisfies requirements expressed by the following expressions (1), (2), and (3). In the expressions (1) to (3), n is an integer greater than or equal to 2, which is the number of the conductive layers in the layered structure 12k. i is an integer from 1 to n. tᵢ is a thickness [m] of an i-th conductive layer in a layering order in the layered structure 12k. ρᵢ is a specific resistance [Ω·m] of the i-th conductive layer. Sᵢ is a Seebeck coefficient [V/K] of the i-th conductive layer, and Sₘ is the Seebeck coefficient of the conductive magnetic body. The first term on the left side of the expression (1) is based on the new finding obtained by the present inventors that the Seebeck coefficient S_{L} of the layered structure 12k can be predicted based on the thickness and specific resistance of each conductive layer. In other words, the first term on the left side of the expression (1) corresponds to the predicted value of the Seebeck coefficient S_{L} of the layered structure 12k. In the thermoelectric conversion element 1a, since these requirements are satisfied, the thermoelectric conversion element 1a is more advantageous from the viewpoint of realizing highly accurate thermal sensing by use of magneto-thermoelectric conversion.

$$\vert {\sum }_{i = 1}^{n} \{ ( {G}_{i} / Y ) \times {S}_{i} \} - {S}_{m} \vert \leq 5 μV / K \qquad ( 1 )$$

$$Y = {\sum }_{i = 1}^{n} {G}_{i} \qquad ( 2 )$$

$${G}_{i} = {t}_{i} / {ρ}_{i} \qquad ( 3 )$$

In the thermoelectric conversion element 1a, the left side of the expression (1) may be 4.8 μV/K or less, may be 4.5 V/K or less, may be 4.0 μV/K or less, may be 3.5 μV/K or less, or may be 3.0 μV/K or less. The left side may be 2.5 μV/K or less, may be 2.0 ρV/K or less, may be 1.0 μV/K or less, may be 0.5 μV/K or less, or may be 0.3 μV/K or less.

The thermoelectric conversion element 1a satisfies requirements shown in the following expressions (4) and (5), for example. In the expression (4), n is an integer greater than or equal to 2, which is the number of the conductive layers in the layered structure 12k. i is an integer from 1 to n. tᵢ is a thickness [m] of an i-th conductive layer in a layering order of the layered structure 12k. ρᵢ is a specific resistance [Ω·m] of the i-th conductive layer. σᵢ is an electric conductivity [S/m] of the i-th conductive layer. In the case where these requirements are satisfied in the thermoelectric conversion element 1a, it is possible to prevent the thicknesses of the conductive layers of the layered structure 12k from greatly differing from each other, while the Seebeck coefficient S_{L} of the connection portion 12 is adjusted to a desired range. In this case, the thermoelectric conversion element 1a is advantageous from the viewpoint of robustness.

$$0.1 \leq n \times ( {G}_{i} / {σ}_{í} ) / {\sum }_{i = 1}^{n} \{ ( {G}_{i} / {σ}_{i} ) \leq 10 \qquad ( 4 )$$

$${G}_{i} = {t}_{i} / {ρ}_{i} \qquad ( 5 )$$

The value of the central physical quantity of the expression (4) may be 0.12 or more, may be 0.15 or more, or may be 0.18 or more. The value of the central physical quantity of the expression (4) may be 8 or less, may be 6 or less, may be 4 or less, or may be 2 or less.

In the layered structure 12k, |S_{AVG}-Sₘ|, which is the absolute value of the difference between the arithmetic mean value S_{AVG} of the Seebeck coefficients of the conductive layers of the layered structure 12k and the Seebeck coefficient Sₘ of the conductive magnetic body included in the thermoelectric conversion body 11, is not limited to a specific value. For example, the absolute value |S_{AVG}-Sₘ| is 10 μV/K or less. In this case, the Seebeck coefficient S_{L} of the connection portion 12 can be easily adjusted to a desired range, and the thermoelectric conversion element 1a is advantageous also from the viewpoint of robustness.

The absolute value |S_{AVG}-Sₘ| may be 8 μV/K or less, may be 6 μV/K or less, may be 4 μV/K or less, may be 2 μV/K or less, or may be 1 μV/K or less.

In the thermoelectric conversion element 1a, the layered structure 12k satisfies requirements shown in the following expressions (6), (7), and (8), for example. In the expressions (6) to (8), n is an integer greater than or equal to 2, which is the number of the conductive layers in the layered structure 12k. i is an integer from 1 to n. tᵢ is a thickness [m] of the i-th conductive layer in a layering order of the layered structure 12k. ρᵢ is the specific resistance [Ω·m] of the i-th conductive layer. Gₘ is conductance [S] in the length direction of the conductive magnetic body. In the case where these requirements are satisfied, the layered structure 12k is likely to have high electric conductivity. Therefore, in the case of using the thermoelectric conversion element 1a to perform heat sensing by use of magneto-thermoelectric conversion, it is likely to be possible to obtain a large output, and the sensitivity of the heat sensing is likely to be improved. Whether or not the requirement of the expression (6) is satisfied is determined by comparing the layered structure 12k and the thermoelectric conversion body 11 of the same length in the length direction (Y-axis direction), for example.

$$Y / {G}_{m} \geq 3 \qquad ( 6 )$$

$$Y = {\sum }_{i = 1}^{n} {G}_{i} \qquad ( 7 )$$

$${G}_{i} = {t}_{i} / {ρ}_{i} \qquad ( 8 )$$

The left side of the expression (6) may be 3.5 or more, may be 4.0 or more, or may be 4.5 or more. For example, the left side of the expression (6) is 20 or less.

The material for forming the conductive layer of the layered structure 12k is not limited to a specific material. For example, in the conductive layer that forms a surface layer in the layered structure 12k, the content of at least one selected from the group consisting of Ti, Cr, Ni, Al, Zn, Nb, Pd, Ag, Ta, W, Pt, and Au is 10% or more based on the number of atoms. In this case, the conductive layer that forms the surface layer tends to have high durability. For example, in the case where the thermoelectric conversion element 1a is manufactured by a method including lithography, the conductive layer forming the surface layer is unlikely be corroded even in a strong basic environment accompanying the lithography.

In the layered structure 12k, the content of at least one selected from the group consisting of Cu, Al, Ag, and Au in at least one of the conductive layers is 50% or more based on the number of atoms. In this case, the layered structure 12k is likely to have a high electric conductivity. Therefore, in the case of using the thermoelectric conversion element 1a to perform heat sensing by use of magneto-thermoelectric conversion, it is likely to be possible to obtain a large output, and the sensitivity of the heat sensing is likely to be improved.

In the layered structure 12k, at least one of the conductive layers may contain a single-component metal. In this case, a precursor of the conductive layer is easily etched by a commercially available etching solution, and manufacture of the thermoelectric conversion element 1a may be facilitated. Although an alloy of a plurality of metals may have corrosion resistance, it may limit chemicals applicable to etching. This may make it difficult to achieve etching selectivity with magnetic bodies, and limitations are likely to be imposed on the element formation process. The conductive layers may include an alloy.

The thermoelectric conversion body 11 includes, for example, a substance exhibiting the anomalous Nernst effect. A substance that exhibits the anomalous Nernst effect is not limited to a specific substance. The substance exhibiting the anomalous Nernst effect is, for example, a magnetic body having a saturation magnetic susceptibility of 5×10⁻³ T or more, or a substance of a band structure with a Weyl point near the Fermi energy. For example, the thermoelectric conversion body 11 contains, as a substance exhibiting the anomalous Nernst effect, at least one substance selected from the group consisting of (i), (ii), (iii), (iv) and (v) below.
(i) A stoichiometric substance having a composition represented by Fe₃X
(ii) An off-stoichiometric substance having a composition ratio of Fe and X that deviates from that of the substance in (i) above
(iii) A substance in which a part of the Fe site of the substance in (i) above or a part of the Fe site in the substance in (ii) above is substituted by a typical metal element or a transition element other than X
(iv) A substance having a composition represented by Fe₃M1₁₋ₓM2ₓ (0<x<1), where M1 and M2 are typical elements different from each other
(v) A substance in which a part of the Fe site of the substance in (i) above is substituted by a transition element other than X, and a part of the X site in the substance in (i) above is substituted by a typical metal element other than X

In the substances (i) to (v), X is a typical element or a transition element. X is, for example, Al, Ga, Ge, Sn, Si, Ti, Zr, Hf, V, Nb, Ta, Cr, Mo, W, Sc, Ni, Mn, or Co. In the above (iv), the combination of M1 and M2 is not limited to a specific combination as long as M1 and M2 are typical elements different from each other. In the above (iv), the combination of M1 and M2 is, for example, Ga and Al, Si and Al, or Ga and B.

The thermoelectric conversion body 11 may contain Co₂MnGa as a substance exhibiting the anomalous Nernst effect, or it may contain an antiferromagnetic body. An example of the antiferromagnetic body is Mn₃Sn.

The thermoelectric conversion body 11 may be an alloy containing Fe and having a body-centered cubic lattice crystal structure. In this case, a large electromotive force is likely to be generated in the thermoelectric conversion body 11 due to the anomalous Nernst effect.

In a case where the thermoelectric conversion body 11 is an alloy containing Fe and having a body-centered cubic lattice crystal structure, the content of Fe and a content of an element other than Fe in the alloy are not limited to specific values. The content of Fe in the alloy is 50% or more based on the number of atoms for example, and the content of the element other than Fe in the alloy is 10% or more based on the number of atoms, for example. In this case, a large electromotive force is likely to be generated in the thermoelectric conversion body 11 due to the anomalous Nernst effect.

The content of Fe in the alloy may be 55% or more, may be 60% or more, may be 65% or more, or may be 70% or more based on the number of atoms. The content of Fe in the alloy may be 90% or less, may be 85% or less, or may be 80% or less based on the number of atoms.

The content of the element other than Fe may be 15% or more, or may be 20% or more based on the number of atoms. The content of the element other than Fe is 50% or less, which may be 40% or less, or may be 30% or less based on the number of atoms.

The magneto-thermoelectric coefficient S_{NE} of the thermoelectric conversion body 11 is not limited to a specific value. The absolute value of magneto-thermoelectric coefficient S_{NE} of the thermoelectric conversion body 11 is 0.5 μV/K or more, for example. As a result, a large electromotive force may be generated easily due to the magneto-thermoelectric conversion in the thermoelectric conversion body 11, and the accuracy in sensing by means of the thermoelectric conversion element 1a can be easily improved. This may facilitate delicate heat sensing. The absolute value of the magneto-thermoelectric coefficient S_{NE} of the thermoelectric conversion body 11 is desirably 1.0 μV/K or more, more desirably 1.5 μV/K or more, and even more desirably 2.0 μV/K or more. The absolute value of the magneto-thermoelectric coefficient S_{NE} of the thermoelectric conversion body 11 may be 3.0 μV/K or more, may be 4.0 μV/K or more, may be 5.0 μV/K or more, may be 6.0 μV/K or more, may be 7.0 μV/K or more, or may be 8.0 μV/K or more.

As shown in FIG. 1 and FIG. 2, the thermoelectric conversion body 11 includes a plurality of first thin wires 11a, for example. The connection portion 12 includes also a plurality of second thin wires 12a. In the thermoelectric conversion element 1a, the first thin wires 11a and the second thin wires 12a are electrically connected to each other in series. With this configuration, the electromotive force caused by the magneto-thermoelectric conversion occurring in the first thin wires 11a is synthesized, making it easy to obtain a large output from the thermoelectric conversion element 1a.

As shown in FIG. 2, in the thermoelectric conversion element 1a, the first thin wires 11a and the second thin wires 12a form a plurality of thin wire pairs 15, for example. Each thin wire pair 15 consists of a first thin wire 11a and a second thin wire 12a. In other words, each thin wire pair 15 consists of one first thin wire 11a and one second thin wire 12a. The number of thin wire pairs 15 in the thermoelectric conversion element 1a is not limited to a specific value. In the thermoelectric conversion element 1a, the first thin wires 11a and the second thin wires 12a form at least fifty thin wire pairs 15, for example. The electromotive force resulting from the Seebeck effect increases as the number of pairs of dissimilar materials joined increases. Meanwhile, in the layered structure 12k of the thermoelectric conversion element 1a, even if the thermoelectric conversion element 1a has fifty or more thin wire pairs 15, the thermal electromotive force tends to be smaller, where the thermal electromotive force resulting from the Seebeck effect is generated in the length direction of the thermoelectric conversion body 11 in a case where a temperature gradient occurs in the length direction.

As shown in FIG. 1 and FIG. 2, the first thin wires 11a and the second thin wires 12a form a meander pattern. With this configuration, even if the area of the plane on which the first thin wires 11a and the second thin wires 12a are disposed is small, a large output can be obtained easily from the thermoelectric conversion element 1a.

As shown in FIG. 1, the first thin wires 11a are disposed spaced apart from each other at predetermined intervals in the X-axis direction and parallel to each other, for example. The first thin wires 11a are disposed at equal intervals in the X-axis direction. The second thin wires 12a electrically connect, for example, the first thin wires 11a adjacent to each other in the X-axis direction. A second thin wire 12a electrically connects, for example, a first end part of a first thin wire 11a in the Y-axis direction and a second end part in the Y-axis direction of another first thin wire 11a adjacent to the first-described first thin wire 11a. The first end parts in the Y-axis direction of the first thin wires 11a are positioned at the end on the same side of the first thin wires 11a in the Y-axis direction, while the second end parts in the Y-axis direction of the first thin wires 11a are positioned at the end opposite to the first end parts in the Y-axis direction of the first thin wires 11a.

The thickness of the first thin wires 11a is not limited to a specific value. The first thin wires 11a have a thickness of 1000 nm or less, for example. Thereby, use amount of the material for the magneto-thermoelectric conversion body in the thermoelectric conversion element 1a can be reduced, and the cost for manufacturing the thermoelectric conversion element 1a can be reduced easily. In addition to that, disconnection of a conductive path formed with the first thin wires 11a and the second thin wires 12a in the thermoelectric conversion element 1a is unlikely to occur.

The thickness of the first thin wires 11a may be 750 nm or less, may be 500 nm or less, may be 400 nm or less, may be 300 nm or less, or may be 200 nm or less. The thickness of the first thin wires 11a is 5 nm or more, for example. Thereby, the thermoelectric conversion element 1a can easily exhibit high durability. The thickness of the first thin wires 11a may be 10 nm or more, may be 20 nm or more, may be 30 nm or more, or may be 50 nm or more.

The width of first thin wires 11a, which is the dimension in the X-axis direction, is not limited to a specific value. The width of the first thin wires 11a is 500 μm or less, for example. Thereby, use amount of the material for the magneto-thermoelectric conversion body in the thermoelectric conversion element 1a can be reduced, and the cost for manufacturing the thermoelectric conversion element 1a can be easily reduced. In addition to that, numbers of the first thin wires 11a can be easily disposed in the X-axis direction, so that the electromotive force generated accompanying the magneto-thermoelectric conversion in thermoelectric conversion element 1a tends to be increased.

The width of the first thin wires 11a may be 400 μm or less, may be 300 μm or less, may be 200 μm or less, may be 100 μm or less, or may be 50 μm or less. The width of the first thin wires 11a is 0.1 μm or more, for example. Thereby, disconnection of a conductive path in the thermoelectric conversion element 1a is unlikely to occur, and the thermoelectric conversion element 1a can easily exhibit high durability. The width of the first thin wires 11a may be 0.5 μm or more, may be 1 μm or more, may be 2 μm or more, may be 5 μm or more, may be 10 μm or more, may be 20 μm or more, or may be 30 μm or more.

The thickness of the second thin wires 12a is not limited to a specific value. The thickness of the second thin wires 12a is 1000 nm, for example. Thereby, use amount of the material for the connection portion 12 can be reduced, and the cost for manufacturing the thermoelectric conversion element 1a can be reduced easily. In addition to that, disconnection of a conductive path in the thermoelectric conversion element 1a is unlikely to occur. The thickness of the second thin wires 12a may be 750 nm or less, may be 500 nm or less, may be 400 nm or less, may be 300 nm or less, may be 200 nm or less, or may be 100 nm or less.

The thickness of the second thin wires 12a is 5 nm or more, for example. Thereby, the thermoelectric conversion element 1a can easily exhibit high durability. The thickness of the second thin wires 12a may be 10 nm or more, may be 20 nm or more, may be 30 nm or more, or may be 50 nm or more.

The width of the second thin wires 12a, which is the maximum dimension in the X-axis direction, is not limited to a specific value. The width of the second thin wires 12a is 500 μm or less, for example. Thereby, use amount of the material for the connection portion 12 in the thermoelectric conversion element 1a can be reduced, and the cost for manufacturing the thermoelectric conversion element 1a can be easily reduced. In addition to that, numbers of the second connection portions 12a can be easily disposed in the X-axis direction, so that the electromotive force generated due to the magneto-thermoelectric conversion in the thermoelectric conversion element 1a tends to be increased.

The width of the second thin wires 12a may be 400 μm or less, may be 300 μm or less, may be 200 μm or less, may be 100 μm or less, or may be 50 μm or less. The width of the second thin wires 12a is 0.1 μm or more, for example. Thereby, disconnection of the conductive path in the thermoelectric conversion element 1a is unlikely to occur, and the thermoelectric conversion element 1a can easily exhibit high durability. The width of the second thin wires 12a may be 0.5 μm or more, may be 1 μm or more, may be 2 μm or more, may be 5 μm or more, may be 10 μm or more, may be 20 μm or more, or may be 30 μm or more.

As shown in FIG. 1, the thermoelectric conversion element 1a includes further a substrate 20. The thermoelectric conversion body 11 and the connection portion 12 are disposed on the substrate 20.

A material for forming the substrate 20 is not limited to a specific material. The substrate 20 does not contain MgO for example, in its surface layer. Since the substrate 20 is not required to contain MgO in its surface layer, production of the thermoelectric conversion element 1a is less complicated, and acid resistance is also easily imparted.

The substrate 20 has flexibility, for example, so that an object to which the thermoelectric conversion element 1a is attached can be shaped with less limitation. In the case where the substrate 20 has flexibility, the substrate 20 may include at least an organic polymer, for example. This may make it possible to reduce the cost for manufacturing the thermoelectric conversion element 1a. Examples of the organic polymer include polyethylene terephthalate (PET), polyethylene naphthalate (PEN), acrylic resin (PMMA), polycarbonate (PC), polyimide (PI), or cycloolefin polymer (COP). The substrate 20 may be an ultrathin glass sheet. An example of ultrathin glass sheet is G-Leaf (registered trademark) manufactured by Nippon Electric Glass Co., Ltd.

An example of the method for manufacturing the thermoelectric conversion element 1a will be explained. First, on one of the principal surfaces of the substrate 20, a thin film for a precursor of the thermoelectric conversion body 11 is formed by any method such as sputtering, chemical vapor deposition (CVD), pulsed laser deposition (PLD), ion plating, or plating. Next, a photoresist is applied onto the thin film, a photomask is disposed above the thin film and exposed, followed by wet etching. As a result, a plurality of linear patterns of the precursor of the thermoelectric conversion body 11 disposed at predetermined intervals are formed. Next, on one of the principal surfaces of the substrate 20, a thin film for precursor of the layered structure 12k is formed by any method such as sputtering, CVD, PLD, ion plating, or plating. In forming the thin film for the precursor of the layered structure 12k, for example, a thin film for the precursor of the first conductive layer 12p is formed, and on the thin film, a thin film for the precursor of the second conductive layer 12p is then formed. Next, a photoresist is applied onto the thin film for precursor of the layered structure 12k, a photomask is disposed above the thin film for precursor of the layered structure 12k and exposed, followed by wet etching. In this manner, the connection portion 12 having the layered structure 12k is obtained, and the linear patterns of the precursor of the thermoelectric conversion body 11 are electrically connected to each other. Next, the precursor of the thermoelectric conversion body 11 is magnetized to form the thermoelectric conversion body 11. A thermoelectric conversion element 1a is obtained in this manner. The precursor of the connection portion 12 may be magnetized to form the connection portion 12, as required. Furthermore, wet etching may be performed on the thin film for the precursor of the conductive layer for every conductive layer in the layered structure 12k.

The thermoelectric conversion element 1a can be provided with a pressure-sensitive adhesive layer, for example. In this case, the substrate 20 is disposed between the thermoelectric conversion body 11 and the pressure-sensitive adhesive layer in the thickness direction of the substrate 20. Thereby, it is possible to attach the thermoelectric conversion element 1a to an article by pressing the pressure-sensitive adhesive layer onto the article.

The pressure-sensitive adhesive layer includes, for example, a rubber-based pressure-sensitive adhesive, an acrylic pressure-sensitive adhesive, a silicone-based pressure-sensitive adhesive, or a urethane-based pressure-sensitive adhesive. The thermoelectric conversion element 1a may be provided together with a pressure-sensitive adhesive layer and a release liner. In this case, the release liner covers the pressure-sensitive adhesive layer. Typically, the release liner is a film that can maintain the adhesiveness of the pressure-sensitive adhesive layer while covering the layer, and it can be peeled off easily from the pressure-sensitive adhesive layer. The release liner is, for example, a film made of a polyester resin like PET. By peeling the release liner off, the pressure-sensitive adhesive layer is exposed and the thermoelectric conversion element 1a can be adhered to an article.

A sensor equipped with the thermoelectric conversion element 1a can be provided. In this sensor, for example, when a temperature gradient occurs in the thickness direction of the substrate 20, an electromotive force is generated by the magneto-thermoelectric effect in the length direction of the thermoelectric conversion body 11. The sensor is capable of sensing heat by processing electric signals output from the thermoelectric conversion element 1a, based on the electromotive force.

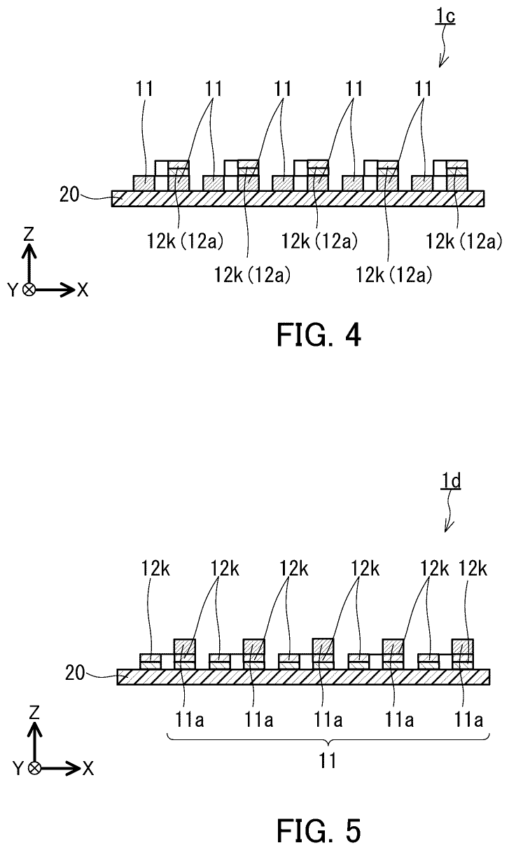

The thermoelectric conversion element 1a can be modified from various viewpoints. For example, the thermoelectric conversion element 1a may be modified to a thermoelectric conversion element 1c as shown in FIG. 4 or a thermoelectric conversion element 1d as shown in FIG. 5. The thermoelectric conversion elements 1c and 1d have the same structure as the thermoelectric conversion element 1a, except for the parts that are specifically explained. Components of the thermoelectric conversion elements 1c and 1d, which are the same as or correspond to those of the thermoelectric conversion element 1a, are given the same reference numerals, and detailed explanations therefor are omitted. The explanations regarding the thermoelectric conversion element 1a also apply to the thermoelectric conversion elements 1c and 1d, unless technically contradictory.

As shown in FIG. 4, in the thermoelectric conversion element 1c, the thermoelectric conversion body 11 extends continuously on the same plane, for example. The layered structure 12k of the connection portion 12 is disposed on a part of the thermoelectric conversion body 11. For example, the second thin wires 12a are disposed spaced apart from each other at predetermined intervals on the thermoelectric conversion body 11. With such a configuration, the thermal electromotive force resulting from the Seebeck effect tends to be small, and the costs for manufacturing the thermoelectric conversion element can be easily reduced.

In the thermoelectric conversion element 1c, the thermoelectric conversion body 11 forms a meander pattern, for example. The thermoelectric conversion element 1c is configured such that a single layer of the thermoelectric conversion body 11 and a layered body including the thermoelectric conversion body 11 and the second thin wire 12a appear alternately in the X-axis direction.

As shown in FIG. 5, in the thermoelectric conversion element 1d, the layered structure 12k of the connection portion 12 extends continuously on the same plane, for example. The thermoelectric conversion body 11 is disposed on a part of the layered structure 12k of the connection portion 12. For example, a plurality of first thin wires 11a are disposed spaced apart from each other at predetermined intervals on the layered structure 12k of the connection portion 12. With this configuration, the thermal electromotive force resulting from the Seebeck effect tends to be small, and the cost for manufacturing the thermoelectric conversion element can be reduced easily.

In the thermoelectric conversion element 1d, the layered structure 12k of the connection portion 12 forms a meander pattern, for example. The thermoelectric conversion element 1c is configured such that the connection portion 12 and a layered body including the connection portion 12 and the first fine wire 11a appear alternately in the X-axis direction.

### EXAMPLES

Hereinafter, the present invention will be described in detail by referring to Examples. It should be noted that the present invention is not limited to the following Examples. First, evaluation methods regarding Examples and Comparative Examples will be explained.

### [Measurement of Seebeck Coefficient]

Using a small-sized refrigerant-free physical property measurement system PPMS VersaLab manufactured by Quantum Design, a Seebeck coefficient Sₘ at a temperature in a range of 27 to 37° C. in the length direction of thin wires for magneto-thermoelectric conversion in a thermoelectric conversion element according to each Example and each Comparative Example, and a Seebeck coefficient S_{L} at a temperature in a range of 27 to 37° C. in the length direction of a wiring (connection portion) were measured. In addition, Seebeck coefficients at a temperature in a range of 27 to 37° C. of the first conductive layers and the second conductive layers of the wirings were measured using separately prepared samples. Each Seebeck coefficient was determined based on a temperature difference and the electromotive force induced between two thermometers attached to each sample at the time that a heat flow was generated by the heater attached to one end of the sample. The Seebeck coefficient at a temperature in a range of 27 to 37° C. of the respective materials that make up the conductive layers of the wirings are shown in Table 1. In addition, arithmetic mean values S_{AVG} of the Seebeck coefficients of the conductive layers of the wirings are shown in Table 2. The Seebeck coefficient Sₘ and the Seebeck coefficient S_{L} are shown in Table 2.

### [Measurement of Magneto-Thermoelectric Coefficient]

Using a small-sized refrigerant-free physical property measurement system PPMS VersaLab manufactured by Quantum Design, the Nernst coefficient at a temperature in a range of 27 to 37° C. of the thin film for thermoelectric conversion element composing thin wires for the magneto-thermoelectric conversion in the thermoelectric conversion element of each Example and each Comparative Example was measured. The Nernst coefficient S_{NE} was 2.0 μV/K.

### [Measurement of Specific Resistance]

Using a non-contact type resistance measuring instrument NC-80MAP manufactured by NAPSON CORPORATION in accordance with Japanese Industrial Standard (JIS) Z 2316-1:2014, a sheet resistance of the thin film for wiring was measured in each Example and each Comparative Example by the eddy current measurement method. A product of the sheet resistance of each thin film and the thickness of each thin film was calculated to determine a specific resistance of each conductive layer. Further, the reciprocal of the specific resistance of each conductive layer was determined as the electric conductivity. The results are shown in Table 1. In addition, the specific resistance of the thermoelectric conversion body composing the thin wire for magneto-thermoelectric conversion was measured in the same manner. Based on these measurement results, the length conductance Gₘ in the length direction of one thin wire for magneto-thermoelectric conversion was obtained. The results are shown in Table 2.

### [Prediction of Seebeck Coefficient]

Based on a specific resistance and a thickness of each conductive layer, the predicted value S_{P} of a Seebeck coefficient of the wiring (connection portion) was calculated using the following expressions (9) and (10). The results are shown in Table 2. In the expressions (9) and (10), t₁ and t₂ are thicknesses [m] of a first conductive layer and a second conductive layer, respectively. ρ₁ and ρ₂ are the specific resistances [Ω·m] of the first conductive layer and the second conductive layer, respectively. S₁ and S₂ are the Seebeck coefficients [V/K] of the materials that compose the first conductive layer and the second conductive layer, respectively.

$${S}_{P} = \{ ( {t}_{1} / {ρ}_{1} ) / Y \} \times {S}_{1} + \{ ( {t}_{2} / {ρ}_{2} ) / Y \} \times {S}_{2} \qquad ( 9 )$$

$$Y = ( {t}_{1} / {ρ}_{1} ) + ( {t}_{2} / {ρ}_{2} ) \qquad ( 10 )$$

[Measurement of Electromotive Force Resulting from Seebeck Effect]

In the plane of a thermoelectric conversion element according to each Example and each Comparative Example, one end in the length direction of the thin wire for thermoelectric conversion and one end in the length direction of the wiring (connection portion) were heated with a heater to cause a temperature difference of 1° C. between the both ends of the thermoelectric conversion thin wire and the both ends of the wiring. In this state, the electromotive force Vs resulting from the Seebeck effect was measured. During the measurement, temperatures on both surfaces of the thermoelectric conversion element were kept constant in order to prevent a temperature gradient in the thickness direction of the thermoelectric conversion element except for one end in the length direction of the thin wire for thermoelectric conversion and wiring. The results are shown in Table 2.

### [Processability]

Evaluation on processability was made based on whether or not the wet etching was possible. A chemical solution was prepared by mixing an etching solution, a hydrogen peroxide solution, and water in a volume ratio of 1:2:2, where the etching solution was a Cu etching solution SF-5420 manufactured by MEC COMPANY LTD., a nickel selective etching solution NC manufactured by NIHON KAGAKU SANGYO CO., LTD., or Melstrip TI-3991 manufactured by Meltex Inc. The processability was evaluated as “A” in the case where the layered film composed of the first conductive layer and the second conductive layer was soluble in these chemical solutions; the processability was evaluated as “X” in the case where the layered film was insoluble in these chemical solutions. In the case where the processability was evaluated as “X”, the lithography process was performed using a liquid in which a nitric acid and a hydrogen peroxide were mixed in a predetermined ratio.

### [Durability]

A layered film composed of the first conductive layer and the second conductive layer was immersed in a 5 mass % NaOH solution for 1 minute, and the appearance of the layered film was then observed. The durability was evaluated as “X” in the case where the surface of the layered film was discolored; the durability was evaluated as “A” in the case where there was no change in the appearance of the surface of the layered film.

### Example 1

A thin film having a thickness of 100 nm was formed on a polyethylene terephthalate (PET) film having a thickness of 50 μm by DC magnetron sputtering, using a target material containing Fe and Ga. In this target material, the atomic ratio of the Fe content to the Ga content was in a relationship of 3:1. A photoresist was applied onto the thin film, a photomask was disposed above the thin film and exposed, followed by wet etching. Thereby, 94 thin wires for magneto-thermoelectric conversion aligned at predetermined intervals were formed. The width of each thin wire for magneto-thermoelectric conversion was 100 μm, and the length of each thin wire for magneto-thermoelectric conversion was 15 mm. After that, a first conductive layer having a thickness of 10 nm was formed by DC magnetron sputtering using a Cu target material. Next, a second conductive layer having a thickness of 101 nm was formed on the first conductive layer by DC magnetron sputtering using a Ni target material. A photoresist was applied onto the layered film consisting of the first conductive layer and the second conductive layer, and a photomask was placed on top of this layered film and exposed, followed by wet etching. Thereby, a wiring (connection portion) with a width of 40 μm was formed. A plurality of thin wires for magneto-thermoelectric conversion were electrically connected to each other in series by the wiring. Further, the thin wires for magneto-thermoelectric conversion and the wiring formed a meander pattern. The thin wires for magneto-thermoelectric conversion were magnetized in a direction parallel to the plane of the PET film and orthogonal to the length direction of the thin wires for magneto-thermoelectric conversion, whereby a thermoelectric conversion element according to Example 1 was obtained. This thermoelectric conversion element generated an electromotive force based on the anomalous Nernst effect.

### Example 2

A thermoelectric conversion element according to Example 2 was manufactured in the same manner as in Example 1 except for the following points. Instead of the Cu target material, a target material with an atomic ratio of Cu content:Ni content=91:9 was used. Using this target material, a first conductive layer having a thickness of 98 nm was formed by DC magnetron sputtering. Instead of the Ni target material, a target material with an atomic ratio of Cu content:Ni content=66:34 was used. A second conductive layer having a thickness of 35 nm was formed on the first conductive layer by DC magnetron sputtering.

### Example 3

A thermoelectric conversion element according to Example 3 was manufactured in the same manner as in Example 2 except for the following points. A first conductive layer having a thickness of 92 nm was formed by DC magnetron sputtering using a target material with an atomic ratio of Cu content:Ni content=91:9.

### Example 4

A thermoelectric conversion element according to Example 4 was manufactured in the same manner as in Example 2 except for the following points. A first conductive layer having a thickness of 84 nm was formed by DC magnetron sputtering using a target material with an atomic ratio of Cu content:Ni content=91:9.

### Example 5

A thermoelectric conversion element according to Example 5 was manufactured in the same manner as in Example 2 except for the following points. A first conductive layer having a thickness of 77 nm was formed by DC magnetron sputtering using a target material with an atomic ratio of Cu content:Ni content=91:9.

### Example 6

A thermoelectric conversion element according to Example 6 was manufactured in the same manner as in Example 2 except for the following points. A first conductive layer having a thickness of 72 nm was formed by DC magnetron sputtering using a target material with an atomic ratio of Cu content:Ni content=91:9.

### Example 7

A thermoelectric conversion element according to Example 7 was manufactured in the same manner as in Example 2 except for the following points. A first conductive layer having a thickness of 67 nm was formed by DC magnetron sputtering using a target material with an atomic ratio of Cu content:Ni content=91:9.

### Example 8

A thermoelectric conversion element according to Example 8 was manufactured in the same manner as in Example 2 except for the following points. A first conductive layer having a thickness of 63 nm was formed by DC magnetron sputtering using a target material with an atomic ratio of Cu content:Ni content=91:9.

### Example 9

A thermoelectric conversion element according to Example 9 was manufactured in the same manner as in Example 2 except for the following points. A first conductive layer having a thickness of 59 nm was formed by DC magnetron sputtering using a target material with an atomic ratio of Cu content:Ni content=91:9.

### Example 10

A thermoelectric conversion element according to Example 10 was manufactured in the same manner as in Example 2 except for the following points. A first conductive layer having a thickness of 52 nm was formed by DC magnetron sputtering using a target material with an atomic ratio of Cu content:Ni content=91:9.

### Example 11

A thermoelectric conversion element according to Example 11 was manufactured in the same manner as Example 1 except for the following points. Instead of the Cu target material, a target material with an atomic ratio of Cu content:Ni content=66:34 was used. Using this target material, a first conductive layer having a thickness of 35 nm was formed by DC magnetron sputtering. Instead of the Ni target material, a target material with an atomic ratio of Cu content:Ni content=91:9 was used. Using this target material, a second conductive layer having a thickness of 98 nm was formed on the first conductive layer by DC magnetron sputtering.

### Example 12

A thermoelectric conversion element according to Example 12 was manufactured in the same manner as Example 1 except for the following points. Instead of the Cu target material, a Ti target material was used. Using this target material, a first conductive layer having a thickness of 77 nm was formed by DC magnetron sputtering. Instead of the Ni target material, a target material with an atomic ratio of Cu content:Ni content=44:56 was used. Using this target material, a second conductive layer having a thickness of 45 nm was formed on the first conductive layer by DC magnetron sputtering.

### Comparative Example 1

A thermoelectric conversion element according to Comparative Example 1 was manufactured in the same manner as Example 1 except for the following points. Instead of the Cu target material, a Ni target material was used. Using this target material, a first conductive layer having a thickness of 101 nm was formed by DC magnetron sputtering. Instead of the Ni target material, a target material with an atomic ratio of Cu content:Ni content=44:56 was used. Using this target material, a second conductive layer with a thickness of 43 nm was formed on the first conductive layer by DC magnetron sputtering.

### Comparative Example 2

A thermoelectric conversion element according to Comparative Example 2 was manufactured in the same manner as Example 1 except for the following points. A first conductive layer having a thickness of 50 nm was formed by DC magnetron sputtering using a target material with an atomic ratio of Fe content:Ga content=3:1. Instead of the Ni target material, a target material with an atomic ratio of Cu content:Ni content=44:56 was used to form a second conductive layer having a thickness of 50 nm on the first conductive layer by DC magnetron sputtering.

### Comparative Example 3

A thermoelectric conversion element according to Comparative Example 3 was manufactured in the same manner as Example 2 except for the following points. A conductive layer having a thickness of 98 nm was formed by DC magnetron sputtering using a target material with an atomic ratio of Cu content:Ni content=91:9. On this conductive layer, any conductive layer corresponding to the second conductive layer of Example 2 was not formed, whereby a conductive layer of a single-layer structure was obtained.

As shown in Table 2, the electromotive force resulting from the Seebeck effect in the thermoelectric conversion element of each Example was smaller than the electromotive force resulting from the Seebeck effect in the thermoelectric conversion element of each Comparative example. Therefore, it was suggested that the electromotive force resulting from the Seebeck effect can be reduced by providing a structure in which a conductive layer having a Seebeck coefficient lower than the Seebeck coefficient of the thermoelectric conversion body is layered with a conductive layer having a Seebeck coefficient higher than the Seebeck coefficient of the thermoelectric conversion body. In addition, it was suggested as advantageous from the viewpoint of reducing the electromotive force resulting from the Seebeck effect that an absolute value of the difference between the Seebeck coefficient of the connection portion having a layered structure of a plurality of conductive layers and the Seebeck coefficient of the conductive magnetic body is 5 μV/K or less. Further, it was suggested that an appropriate selection of the composition of the outermost layer of the laminated structure of the conductive layer results in improved durability, and the layered structure is capable of achieving both a reduction in electromotive force resulting from the Seebeck effect and durability. In the thermoelectric conversion element according to Comparative Example 3, the electromotive force resulting from the Seebeck effect was reduced by using a single conductive layer having a Seebeck coefficient close to the Seebeck coefficient of the thermoelectric conversion body, but the durability was inferior.

A first aspect of the present invention provides a thermoelectric conversion element including:
a thermoelectric conversion body including a conductive magnetic body containing a ferromagnetic body or an antiferromagnetic body capable of exhibiting an anomalous Nernst effect, and the thermoelectric conversion body extending linearly; and
a connection portion including a conductive body and electrically connected to the thermoelectric conversion body, wherein
the connection portion has a layered structure composed of a plurality of conductive layers, and
the layered structure includes a first conductive layer having a Seebeck coefficient lower than a Seebeck coefficient of the conductive magnetic body, and a second conductive layer having a Seebeck coefficient higher than the Seebeck coefficient of the conductive magnetic body.

A second aspect of the present invention provides a thermoelectric conversion element including:
a thermoelectric conversion body including a conductive magnetic body containing a ferromagnetic body or an antiferromagnetic body capable of exhibiting an anomalous Nernst effect, and the thermoelectric conversion body extending linearly; and
a connection portion including a conductive body and electrically connected to the thermoelectric conversion body, wherein
the connection portion has a layered structure composed of a plurality of conductive layers, and
an absolute value of a difference between a Seebeck coefficient of the connection portion and a Seebeck coefficient of the conductive magnetic body is 5 μV/K or less.

A third aspect of the present invention provides the thermoelectric conversion element according to the first or second aspect, wherein the layered structure satisfies requirements expressed by the following expressions (1), (2), and (3),
where n is an integer greater than or equal to 2, which is the number of the conductive layers in the layered structure; i is an integer from 1 to n; tᵢ is a thickness of an i-th conductive layer in a layering order in the layered structure; ρᵢ is a specific resistance of the i-th conductive layer; Sᵢ is a Seebeck coefficient of the i-th conductive layer; and Sₘ is the Seebeck coefficient of the conductive magnetic body.

$$\vert {\sum }_{i = 1}^{n} \{ ( {G}_{i} / Y ) \times {S}_{i} \} - {S}_{m} \vert \leq 5 μV / K \qquad ( 1 )$$

$$Y = {\sum }_{i = 1}^{n} {G}_{i} \qquad ( 2 )$$

$${G}_{i} = {t}_{i} / {ρ}_{i} \qquad ( 3 )$$

A fourth aspect of the present invention provides the thermoelectric conversion element according to any one of the first to third aspects, wherein
the layered structure satisfies requirements expressed by the following expressions (4) and (5),
where n is an integer greater than or equal to 2, which is the number of the conductive layers in the layered structure; i is an integer from 1 to n; tᵢ is a thickness of an i-th conductive layer in a layering order in the layered structure; ρᵢ is a specific resistance of the i-th conductive layer; and σᵢ is an electric conductivity of the i-th conductive layer.

$$0.1 \leq n \times ( {G}_{i} / {σ}_{í} ) / {\sum }_{i = 1}^{n} \{ ( {G}_{i} / {σ}_{i} ) \leq 10 \qquad ( 4 )$$

$${G}_{i} = {t}_{i} / {ρ}_{i} \qquad ( 5 )$$

A fifth aspect of the present invention provides the thermoelectric conversion element according to any one of the first to fourth aspects, wherein
an absolute value of a difference between an arithmetic mean value of Seebeck coefficients of the conductive layers and the Seebeck coefficient of the conductive magnetic body is 10 μV/K or less.

A sixth aspect of the present invention provides the thermoelectric conversion element according to any one of the first to fifth aspects, wherein
a content of at least one selected from the group consisting of Ti, Cr, Ni, Al, Zn, Nb, Pd, Ag, Ta, W, Pt, and Au in the conductive layer forming a surface layer of the layered structure is 10% or more based on the number of atoms.

A seventh aspect of the present invention provides the thermoelectric conversion element according to any one of the first to sixth aspects, wherein
a content of at least one selected from the group consisting of Cu, Al, Ag, and Au in at least one of the conductive layers is 50% or more based on the number of atoms.

An eighth aspect of the present invention provides the thermoelectric conversion element according to any one of the first to seventh aspects, wherein
the layered structure satisfies requirements expressed by the following expressions (6), (7), and (8),
where n is an integer greater than or equal to 2, which is the number of the conductive layers in the layered structure; i is an integer from 1 to n; tᵢ is a thickness of an i-th conductive layer in a layering order in the layered structure; ρᵢ is a specific resistance of the i-th conductive layer; and Gₘ is conductance in a length direction of the conductive magnetic body.

$$Y / {G}_{m} \geq 3 \qquad ( 6 )$$

$$Y = {\sum }_{i = 1}^{n} {G}_{i} \qquad ( 7 )$$

$${G}_{i} = {t}_{i} / {ρ}_{i} \qquad ( 8 )$$

A ninth aspect of the present invention provides the thermoelectric conversion element according to any one of the first to the eighth aspects, wherein
at least one of the conductive layers includes a single-component metal.

A tenth aspect of the present invention provides the thermoelectric conversion element according to any one of the first to ninth aspects, wherein
the thermoelectric conversion body has a plurality of first thin wires,
the connection portion has a plurality of second thin wires, and
the first thin wires and the second thin wires are electrically connected to each other in series.

An eleventh aspect of the present invention provides the thermoelectric conversion element according to the tenth aspect, wherein
the first thin wires and the second thin wires form fifty or more thin wire pairs, and
each of the fifty or more thin wire pairs consists of the first thin wire and the second thin wire.

A twelfth aspect of the present invention provides the thermoelectric conversion element according to the tenth or eleventh aspect, wherein
the first thin wires and the second thin wires form a meander pattern.

A thirteenth aspect of the present invention provides a sensor including the thermoelectric conversion element according to any one of the first to twelfth aspects.

TABLE 1

| | | Conductive layer | | |
|---|---|---|---|---|
| | | | Specific | Electric |
| | | | resistance ρ | conductivity σ |
| | | Material | [10⁻⁶ Ω · cm] | [10⁶ S/m] |
| Example 1 | Second conductive layer | Ni | 14.5 | 6.9 |
| | First conductive layer | Cu | 6.9 | 14.5 |
| Example 2 | Second conductive layer | Cu₆₆Ni₃₄ | 48 | 2.1 |
| | First conductive layer | Cu₉₁Ni₉ | 16.9 | 5.9 |
| Example 3 | Second conductive layer | Cu₆₆Ni₃₄ | 48 | 2.1 |
| | First conductive layer | Cu₉₁Ni₉ | 16.9 | 5.9 |
| Example 4 | Second conductive layer | Cu₆₆Ni₃₄ | 48 | 2.1 |
| | First conductive layer | Cu₉₁Ni₉ | 16.9 | 5.9 |
| Example 5 | Second conductive layer | Cu₆₆Ni₃₄ | 48 | 2.1 |
| | First conductive layer | Cu₉₁Ni₉ | 16.9 | 5.9 |
| Example 6 | Second conductive layer | Cu₆₆Ni₃₄ | 48 | 2.1 |
| | First conductive layer | Cu₉₁Ni₉ | 16.9 | 5.9 |
| Example 7 | Second conductive layer | Cu₆₆Ni₃₄ | 48 | 2.1 |
| | First conductive layer | Cu₉₁Ni₉ | 16.9 | 5.9 |
| Example 8 | Second conductive layer | Cu₆₆Ni₃₄ | 48 | 2.1 |
| | First conductive layer | Cu₉₁Ni₉ | 16.9 | 5.9 |
| Example 9 | Second conductive layer | Cu₆₆Ni₃₄ | 48 | 2.1 |
| | First conductive layer | Cu₉₁Ni₉ | 16.9 | 5.9 |
| Example 10 | Second conductive layer | Cu₆₆Ni₃₄ | 48 | 2.1 |
| | First conductive layer | Cu₉₁Ni₉ | 16.9 | 5.9 |
| Example 11 | Second conductive layer | Cu₉₁Ni₉ | 16.9 | 5.9 |
| | First conductive layer | CU₆₆Ni₃₄ | 48 | 2.1 |
| Example 12 | Second conductive layer | Cu₄₄Ni₅₆ | 60.9 | 1.6 |
| | First conductive layer | Ti | 129 | 0.8 |
| Comparative | Second conductive layer | Cu₄₄Ni₅₆ | 60.9 | 1.6 |
| Example 1 | First conductive layer | Ni | 14.5 | 6.9 |
| Comparative | Second conductive layer | Cu₄₄Ni₅₆ | 60.9 | 1.6 |
| Example 2 | First conductive layer | Fe₃Ga | 100.0 | 1.0 |
| Comparative | Conductive layer | Cu₉₁Ni₉ | 16.9 | 5.9 |
| Example 3 | | | | |

| | | Conductive layer | | | |
|---|---|---|---|---|---|
| | | Thickness | | Seebeck | |
| | | t | G(t/ρ) | coefficient | n × (Gi/σi)/ |
| | | [nm] | [10⁻³ S] | [μV/K] | (ΣGi/σi) |
| Example 1 | Second conductive layer | 101 | 697 | −21.5 | 1.82 |
| | First conductive layer | 10 | 145 | 2.3 | 0.18 |
| Example 2 | Second conductive layer | 35 | 73 | −22.2 | 0.53 |
| | First conductive layer | 98 | 580 | −16.8 | 1.47 |
| Example 3 | Second conductive layer | 35 | 73 | −22.2 | 0.55 |
| | First conductive layer | 92 | 544 | −16.8 | 1.45 |
| Example 4 | Second conductive layer | 35 | 73 | −22.2 | 0.59 |
| | First conductive layer | 84 | 497 | −16.8 | 1.41 |
| Example 5 | Second conductive layer | 35 | 73 | −22.2 | 0.63 |
| | First conductive layer | 77 | 456 | −16.8 | 1.38 |
| Example 6 | Second conductive layer | 35 | 73 | −22.2 | 0.65 |
| | First conductive layer | 72 | 426 | −16.8 | 1.35 |
| Example 7 | Second conductive layer | 35 | 73 | −22.2 | 0.69 |
| | First conductive layer | 67 | 396 | −16.8 | 1.31 |
| Example 8 | Second conductive layer | 35 | 73 | −22.2 | 0.71 |
| | First conductive layer | 63 | 373 | −16.8 | 1.29 |
| Example 9 | Second conductive layer | 35 | 73 | −22.2 | 0.74 |
| | First conductive layer | 59 | 349 | −16.8 | 1.26 |
| Example 10 | Second conductive layer | 35 | 73 | −22.2 | 0.80 |
| | First conductive layer | 52 | 308 | −16.8 | 1.20 |
| Example 11 | Second conductive layer | 98 | 580 | −16.8 | 1.47 |
| | First conductive layer | 35 | 73 | −22.2 | 0.53 |
| Example 12 | Second conductive layer | 45 | 74 | −34 | 0.74 |
| | First conductive layer | 77 | 60 | 3.2 | 1.26 |
| Comparative | Second conductive layer | 43 | 71 | −34.0 | 0.60 |
| Example 1 | First conductive layer | 101 | 697 | −21.5 | 1.40 |
| Comparative | Second conductive layer | 50 | 82 | −34.0 | 1.00 |
| Example 2 | First conductive layer | 50 | 50 | −17.4 | 1.00 |
| Comparative | Conductive layer | 98 | 580 | −16.8 | 1.00 |
| Example 3 | | | | | |

TABLE 2

| | Layered body of conductive layers | | | | | |
|---|---|---|---|---|---|---|
| | Arithmetic mean | | | Thermoelectric conversion body | | |
| | value of Seebeck | | | | Seebeck | |
| | coefficient S_{AVG} | Υ(ΣGi) | | | coefficient Sₘ | Gₘ |
| | [μV/K] | [10⁻³ S] | ΣGi/σi | Material | [μV/K] | [10⁻³ S] |
| Example 1 | −9.6 | 841 | 1.1.E−07 | Fe₃Ga | −17.4 | 100 |
| Example 2 | −19.5 | 653 | 1.3.E−07 | Fe₃Ga | −17.4 | 100 |
| Example 3 | −19.5 | 617 | 1.3.E−07 | Fe₃Ga | −17.4 | 100 |
| Example 4 | −19.5 | 570 | 1.2.E−07 | Fe₃Ga | −17.4 | 100 |
| Example 5 | −19.5 | 529 | 1.1.E−07 | Fe₃Ga | −17.4 | 100 |
| Example 6 | −19.5 | 499 | 1.1.E−07 | Fe₃Ga | −17.4 | 100 |
| Example 7 | −19.5 | 469 | 1.0.E−07 | Fe₃Ga | −17.4 | 100 |
| Example 8 | −19.5 | 446 | 9.8.E−08 | Fe₃Ga | −17.4 | 100 |
| Example 9 | −19.5 | 422 | 9.4.E−08 | Fe₃Ga | −17.4 | 100 |
| Example 10 | −19.5 | 381 | 8.7.E−08 | Fe₃Ga | −17.4 | 100 |
| Example 11 | −19.5 | 653 | 1.3.E−07 | Fe₃Ga | −17.4 | 100 |
| Example 12 | −15.4 | 134 | 1.2.E−07 | Fe₃Ga | −17.4 | 100 |
| Comparative | −27.8 | 767 | 1.4.E−07 | Fe³Ga | −17.4 | 100 |
| Example 1 | | | | | | |
| Comparative | −25.7 | 132 | 1.0.E−07 | Fe₃Ga | −17.4 | 100 |
| Example 2 | | | | | | |
| Comparative | −16.8 | 580 | 9.8.E−08 | Fe₃Ga | −17.4 | 100 |
| Example 3 | | | | | | |

| | Evaluation | | | | |
|---|---|---|---|---|---|
| | | Predicted | | | |
| | Measured | value of | Seebeck | | |
| | value of | Seebeck | coefficient | Seebeck | Seebeck |
| | Seebeck | coefficient S_{P} | difference | coefficient | coefficient |
| | coefficient S_{L} | Σ(Gi/Y × Si) | \|S_{L} − Sₘ\| | difference | difference |
| | [μV/K] | [μV/K] | μV/K] | \|S_{P} − Sₘ\|[μV/K] | \|S_{AVG} − Sₘ\|[μV/K] |
| Example 1 | −17.4 | −17.4 | 0.0 | 0.00 | 7.80 |
| Example 2 | −17.5 | −17.4 | 0.1 | 0.00 | 2.10 |
| Example 3 | −17.4 | −17.4 | 0.0 | 0.04 | 2.10 |
| Example 4 | −17.6 | −17.5 | 0.2 | 0.09 | 2.10 |
| Example 5 | −17.6 | −17.5 | 0.2 | 0.14 | 2.10 |
| Example 6 | −17.7 | −17.6 | 0.3 | 0.19 | 2.10 |
| Example 7 | −17.7 | −17.6 | 0.3 | 0.24 | 2.10 |
| Example 8 | −17.8 | −17.7 | 0.4 | 0.28 | 2.10 |
| Example 9 | −17.8 | −17.7 | 0.4 | 0.33 | 2.10 |
| Example 10 | −17.9 | −17.8 | 0.5 | 0.43 | 2.10 |
| Example 11 | −17.5 | −17.4 | 0.1 | 0.00 | 2.1 |
| Example 12 | −17.4 | −17.4 | 0.0 | 0.02 | 2.00 |
| Comparative | −22.8 | −22.7 | 5.4 | 5.25 | 10.35 |
| Example 1 | | | | | |
| Comparative | −27.9 | −27.7 | 10.5 | 10.32 | 8.30 |
| Example 2 | | | | | |
| Comparative | −16.8 | −16.8 | 0.6 | 0.60 | 0.60 |
| Example 3 | | | | | |

| | Evaluation | | | | |
|---|---|---|---|---|---|
| | | Seebeck | Thermal | | |
| | | electromotive | electromotive | | |
| | | force | force | | |
| | Y/Gₘ | [μV] | [μV] | Processability | Durability |
| Example 1 | 8.41 | 0 | 1.06 | A | A |
| Example 2 | 6.53 | 0 | 0.98 | X | A |
| Example 3 | 6.17 | 4 | 0.96 | X | A |
| Example 4 | 5.70 | 9 | 0.94 | X | A |
| Example 5 | 5.29 | 14 | 0.91 | X | A |
| Example 6 | 4.99 | 19 | 0.90 | X | A |
| Example 7 | 4.69 | 24 | 0.88 | X | A |
| Example 8 | 4.46 | 28 | 0.86 | X | A |
| Example 9 | 4.22 | 33 | 0.84 | X | A |
| Example 10 | 3.81 | 43 | 0.81 | X | A |
| Example 11 | 6.53 | 0 | 0.98 | X | X |
| Example 12 | 1.34 | 2 | 0.48 | X | A |
| Comparative | 7.67 | 525 | 1.03 | X | A |
| Example 1 | | | | | |
| Comparative | 1.32 | 1032 | 0.48 | X | A |
| Example 2 | | | | | |
| Comparative | 5.80 | 60 | 0.95 | X | X |
| Example 3 | | | | | |

1. A thermoelectric conversion element comprising:
a thermoelectric conversion body including a conductive magnetic body containing a ferromagnetic body or an antiferromagnetic body capable of exhibiting an anomalous Nernst effect, and the thermoelectric conversion body extending linearly; and
a connection portion including a conductive body and electrically connected to the thermoelectric conversion body, wherein
the connection portion has a layered structure composed of a plurality of conductive layers, and
the layered structure includes a first conductive layer having a Seebeck coefficient lower than a Seebeck coefficient of the conductive magnetic body, and a second conductive layer having a Seebeck coefficient higher than the Seebeck coefficient of the conductive magnetic body.

2. A thermoelectric conversion element comprising:
a thermoelectric conversion body including a conductive magnetic body containing a ferromagnetic body or an antiferromagnetic body capable of exhibiting an anomalous Nernst effect, and the thermoelectric conversion body extending linearly; and
a connection portion including a conductive body and electrically connected to the thermoelectric conversion body, wherein
the connection portion has a layered structure composed of a plurality of conductive layers, and
an absolute value of a difference between a Seebeck coefficient of the connection portion and a Seebeck coefficient of the conductive magnetic body is 5 μV/K or less.

3. The thermoelectric conversion element according to claim 1, wherein
the layered structure satisfies requirements expressed by the following expressions (1), (2), and (3):
$$\vert {\sum }_{i = 1}^{n} \{ ( {G}_{i} / Y ) \times {S}_{i} \} - {S}_{m} \vert \leq 5 μV / K \qquad ( 1 )$$
$$Y = {\sum }_{i = 1}^{n} {G}_{i} \qquad ( 2 )$$
$${G}_{i} = {t}_{i} / {ρ}_{i} \qquad ( 3 )$$
where n is an integer greater than or equal to 2, which is the number of the conductive layers in the layered structure; i is an integer from 1 to n; tᵢ is a thickness of an i-th conductive layer in a layering order in the layered structure; ρᵢ is a specific resistance of the i-th conductive layer; Sᵢ is a Seebeck coefficient of the i-th conductive layer; and Sₘ is the Seebeck coefficient of the conductive magnetic body.

4. The thermoelectric conversion element according to claim 1, wherein
the layered structure satisfies requirements expressed by the following expressions (4) and (5):
$$0.1 \leq n \times ( {G}_{i} / {σ}_{í} ) / {\sum }_{i = 1}^{n} \{ ( {G}_{i} / {σ}_{i} ) \leq 10 \qquad ( 4 )$$
$${G}_{i} = {t}_{i} / {ρ}_{i} \qquad ( 5 )$$
where n is an integer greater than or equal to 2, which is the number of the conductive layers in the layered structure; i is an integer from 1 to n; tᵢ is a thickness of an i-th conductive layer in a layering order in the layered structure; ρᵢ is a specific resistance of the i-th conductive layer; and σᵢ is an electric conductivity of the i-th conductive layer.

5. The thermoelectric conversion element according to claim 1, wherein
an absolute value of a difference between an arithmetic mean value of Seebeck coefficients of the conductive layers and the Seebeck coefficient of the conductive magnetic body is 10 μV/K or less.

6. The thermoelectric conversion element according to claim 1, wherein
a content of at least one selected from the group consisting of Ti, Cr, Ni, Al, Zn, Nb, Pd, Ag, Ta, W, Pt, and Au in the conductive layer forming a surface layer of the layered structure is 10% or more based on the number of atoms.

7. The thermoelectric conversion element according to claim 1, wherein
a content of at least one selected from the group consisting of Cu, Al, Ag, and Au in at least one of the conductive layers is 50% or more based on the number of atoms.

8. The thermoelectric conversion element according to claim 1, wherein
the layered structure satisfies requirements expressed by the following expressions (6), (7), and (8):
$$Y / {G}_{m} \geq 3 \qquad ( 6 )$$
$$Y = {\sum }_{i = 1}^{n} {G}_{i} \qquad ( 7 )$$
$${G}_{i} = {t}_{i} / {ρ}_{i} \qquad ( 8 )$$
where n is an integer greater than or equal to 2, which is the number of the conductive layers in the layered structure; i is an integer from 1 to n; tᵢ is a thickness of an i-th conductive layer in a layering order in the layered structure; ρᵢ is a specific resistance of the i-th conductive layer; and Gₘ is conductance in a length direction of the conductive magnetic body.

9. The thermoelectric conversion element according to claim 1, wherein
at least one of the conductive layers includes a single-component metal.

10. The thermoelectric conversion element according to claim 1, wherein
the thermoelectric conversion body has a plurality of first thin wires,
the connection portion has a plurality of second thin wires, and
the first thin wires and the second thin wires are electrically connected to each other in series.

11. The thermoelectric conversion element according to claim 10, wherein
the first thin wires and the second thin wires form fifty or more thin wire pairs, and
each of the fifty or more thin wire pairs consists of the first thin wire and the second thin wire.

12. The thermoelectric conversion element according to claim 10, wherein
the first thin wires and the second thin wires form a meander pattern.

13. A sensor comprising the thermoelectric conversion element according to claim 1.

14. The thermoelectric conversion element according to claim 2, wherein
the layered structure satisfies requirements expressed by the following expressions (1), (2), and (3):
$$\vert {\sum }_{i = 1}^{n} \{ ( {G}_{i} / Y ) \times {S}_{i} \} - {S}_{m} \vert \leq 5 μV / K \qquad ( 1 )$$
$$Y = {\sum }_{i = 1}^{n} {G}_{i} \qquad ( 2 )$$
$${G}_{i} = {t}_{i} / {ρ}_{i} \qquad ( 3 )$$
where n is an integer greater than or equal to 2, which is the number of the conductive layers in the layered structure; i is an integer from 1 to n; tᵢ is a thickness of an i-th conductive layer in a layering order in the layered structure; ρᵢ is a specific resistance of the i-th conductive layer; Sᵢ is a Seebeck coefficient of the i-th conductive layer; and Sₘ is the Seebeck coefficient of the conductive magnetic body.

15. The thermoelectric conversion element according to claim 2, wherein
the layered structure satisfies requirements expressed by the following expressions (4) and (5):
$$0.1 \leq n \times ( {G}_{i} / {σ}_{í} ) / {\sum }_{i = 1}^{n} \{ ( {G}_{i} / {σ}_{i} ) \leq 10 \qquad ( 4 )$$
$${G}_{i} = {t}_{i} / {ρ}_{i} \qquad ( 5 )$$
where n is an integer greater than or equal to 2, which is the number of the conductive layers in the layered structure; i is an integer from 1 to n; tᵢ is a thickness of an i-th conductive layer in a layering order in the layered structure; ρᵢ is a specific resistance of the i-th conductive layer; and σᵢ is an electric conductivity of the i-th conductive layer.

16. The thermoelectric conversion element according to claim 2, wherein
an absolute value of a difference between an arithmetic mean value of Seebeck coefficients of the conductive layers and the Seebeck coefficient of the conductive magnetic body is 10 μV/K or less.

17. The thermoelectric conversion element according to claim 2, wherein
a content of at least one selected from the group consisting of Ti, Cr, Ni, Al, Zn, Nb, Pd, Ag, Ta, W, Pt, and Au in the conductive layer forming a surface layer of the layered structure is 10% or more based on the number of atoms.

18. The thermoelectric conversion element according to claim 2, wherein
a content of at least one selected from the group consisting of Cu, Al, Ag, and Au in at least one of the conductive layers is 50% or more based on the number of atoms.

19. The thermoelectric conversion element according to claim 2, wherein
the layered structure satisfies requirements expressed by the following expressions (6), (7), and (8):
$$Y / {G}_{m} \geq 3 \qquad ( 6 )$$
$$Y = {\sum }_{i = 1}^{n} {G}_{i} \qquad ( 7 )$$
$${G}_{i} = {t}_{i} / {ρ}_{i} \qquad ( 8 )$$
where n is an integer greater than or equal to 2, which is the number of the conductive layers in the layered structure; i is an integer from 1 to n; tᵢ is a thickness of an i-th conductive layer in a layering order in the layered structure; ρᵢ is a specific resistance of the i-th conductive layer; and Gₘ is conductance in a length direction of the conductive magnetic body.

20. The thermoelectric conversion element according to claim 2, wherein
at least one of the conductive layers includes a single-component metal.

21. The thermoelectric conversion element according to claim 2, wherein
the thermoelectric conversion body has a plurality of first thin wires,
the connection portion has a plurality of second thin wires, and
the first thin wires and the second thin wires are electrically connected to each other in series.

22. A sensor comprising the thermoelectric conversion element according to claim 2.
